(19) United States
(12) Patent Application Publication
(10) Pub. No.: US 2024/0167153 A1
(43) Pub. Date: May 23, 2024

(54) IN-SITU FILM ANNEALING IN SUBSTRATE PROCESSING

(71) Applicant: Lam Research Corporation, Fremont, CA (US)

(72) Inventors: Awnish Gupta, Hillsboro, OR (US); Douglas Walter Agnew, Portland, OR (US); Bart Jan van Schravendijk, Palo Alto, CA (US); Joseph R. Abel, West Linn, OR (US); Frank L. Pasquale, Beaverton, OR (US); Adrien Lavoie, Newberg, OR (US)

(21) Appl. No.: 18/283,796

(22) PCT Filed: Mar. 25, 2022
(86) PCT No.: PCT/US2022/021946

§ 371 Date: Sep. 23, 2023

Related U.S. Application Data
(60) Provisional application No. 63/168,217, filed on Mar. 30, 2021.

(51) Int. Cl. C23C 16/455; C23C 16/56

(52) U.S. Cl. CPC C23C 16/45536; C23C 16/45512; C23C 16/45534; C23C 16/56

(57) ABSTRACT

In one example, a method for depositing a film on a substrate comprises arranging a substrate on a substrate support in a processing chamber and setting a processing pressure, temperature and pressure in the chamber. The method includes striking a plasma and depositing and annealing the film on the substrate at a thickness in a predetermined film thickness range.

### CLAIM OF PRIORITY

This application claims the benefit of priority to U.S. Provisional Patent Application Ser. No. 63/168,217, filed on Mar. 30, 2021, which is incorporated by reference herein in its entirety.

### FIELD

The present disclosure relates to substrate processing systems, and more particularly to systems and methods for in-situ annealing of a film or substrate containing silicon dioxide (SiO₂).

### BACKGROUND

Substrate processing systems may be used to deposit film on substrates such as semiconductor wafers. Example processes that may be performed on a substrate include, but are not limited to, chemical vapor deposition (CVD), atomic layer deposition (ALD), plasma-enhanced CVD (PECVD), and plasma-enhanced ALD (PEALD). A substrate may be arranged on a substrate support, such as a pedestal, an electrostatic chuck (ESC), etc., in a processing chamber of the substrate processing system. During processing, a gas mixture is introduced into the processing chamber and plasma may be used to enhance chemical reactions within the processing chamber.

ALD is a method of conformal deposition. As more and more material is deposited into a feature under ALD, the aspect ratio of the resulting structure increases as gap fill progresses. At some point, the aspect ratio of the structure to be filled may approach infinity. At this point, it becomes more and more difficult for the depositing reactants to enter the structure, such as a trench. As a result a line of weakness or poor-quality film, called a “seam”, may be formed at the middle of the trench sidewalls. Wet etch rates (WERs) at this seam are unfavorably high compared to second WERs at a free sidewall, for example.

Attempts to improve the film quality of the seam have included annealing an affected substrate with nitrogen in an external tool or furnace at high temperature (e.g. 900° C. or more), but these attempts increase complexity and expense, may not be compatible with advanced devices due to the high thermal budget and have not proven fully reliable at removing seams.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

In some examples, a system for depositing a film on a substrate is provided. An example system comprises a processing chamber; a substrate support for supporting a substrate in the processing chamber; a pressurizer configurable to set a processing and annealing pressure in the processing chamber to a predetermined pressure range, the annealing pressure set for in-chamber annealing of the film; a heater configurable to set a processing and annealing temperature of the processing chamber or the substrate support to a predetermined temperature, the annealing temperature set for in-chamber annealing of the film; a gas distribution device configurable to receive a supply of a process gas mixture and a film annealing gas mixture, wherein the process gas mixture includes a precursor gas, a dopant, a gas including a first oxygen species, and an inert gas, such as helium or argon gas, and wherein the film annealing gas mixture includes a second oxygen species, or a hydrogen species; an electrode for striking a plasma; and deposition means configured to deposit and anneal the film on the substrate at a thickness in a predetermined thickness range.

In some examples, the hydrogen species of the annealing gas mixture includes hydrogen (H₂) introduced at a flow rate in the range 500-10000 standard cubic centimeters per minute (sccm) into a multi-station processing tool, for example a four station tool 200 of FIG. 2. In some examples, H₂ is introduced at a flow rate in the range 50-100 slm (50,000-100,000 sccm) into a single processing station. In some examples, an annealing temperature, or ambient temperature, is determined by a ratio of constituents in an annealing gas, a annealing gas ratio, or a gas pressure ratio. In some examples, an annealing ambient temperature is derived independently of a gas flow rate.

In some examples, the second oxygen species of the annealing gas mixture includes oxygen (O₂) introduced at a flow rate in the range 500-10000 sccm into a multi-station processing tool, for example a four station tool 200 of FIG. 2. In some examples, O₂ is introduced at a flow rate in the range 50-100 slm (50,000-100,000 sccm) into a single processing station.

Further areas of applicability of the present disclosure will become apparent from the detailed description, the claims, and the drawings. The detailed description and specific examples are intended for purposes of illustration only and are not intended to limit the scope of the disclosure.

### DESCRIPTION OF THE DRAWINGS

Some embodiments are illustrated by way of example and not limitation in the views of the accompanying drawings:

FIG. 1 depicts a schematic illustration of an embodiment of an atomic layer deposition (ALD) process station, according to an example embodiment.

FIG. 2 is a schematic view of a substrate processing tool, according to an example embodiment.

FIGS. 3A-3B, and FIGS. 4A-4E are diagrams depicting example operations and aspects in methods of processing a substrate, according to example embodiments.

FIGS. 5-8 include graphs depicting wet etch data for films annealed according to some example embodiments.

FIGS. 9A-9B illustrate film seams and substrate portions, in accordance with example embodiments.

FIG. 10 is a flow chart including example operations in a method of processing a substrate, according to an example embodiment.

FIG. 11 is a block diagram illustrating an example of a system controller upon which one or more example embodiments may be implemented, or by which one or more example embodiments may be controlled.

### DESCRIPTION

The description that follows includes systems, methods, techniques, instruction sequences, and computing machine program products that embody illustrative embodiments of the present inventive subject matter. In the following description, for purposes of explanation, numerous specific details are set forth in order to provide a thorough understanding of example embodiments. It will be evident, however, to one skilled in the art, that the present embodiments may be practiced without these specific details.

In some examples, an in-situ annealing operation is used in the production of a substrate or wafer film in which formation of a seam in a feature is avoided or reduced. In some examples, an in-situ annealing operation includes introducing hydrogen (H₂) or oxygen (O₂), or a mixture of the two gases, into a substrate processing chamber at high pressure to support a thermal anneal at temperatures in excess of 600° Centigrade. In some examples, a thermal annealing range includes temperatures from 600° Centigrade to 10000 Centigrade. In some examples, a thermal annealing range includes temperatures from 5000 Centigrade to 2000° Centigrade. Other ranges are possible. In some examples of this disclosure, the in-situ annealing operations, or examples, which include or reference introducing (H₂) and oxygen (O₂) into a processing chamber are referred to by the acronym H₂/O₂. In some examples, based on WERs, film quality improves by 30% over a conventional nitrogen (N₂)-based annealing. In some examples, film quality improvement, especially at a seam in ALD deposition, has a profound impact on the seam quality.

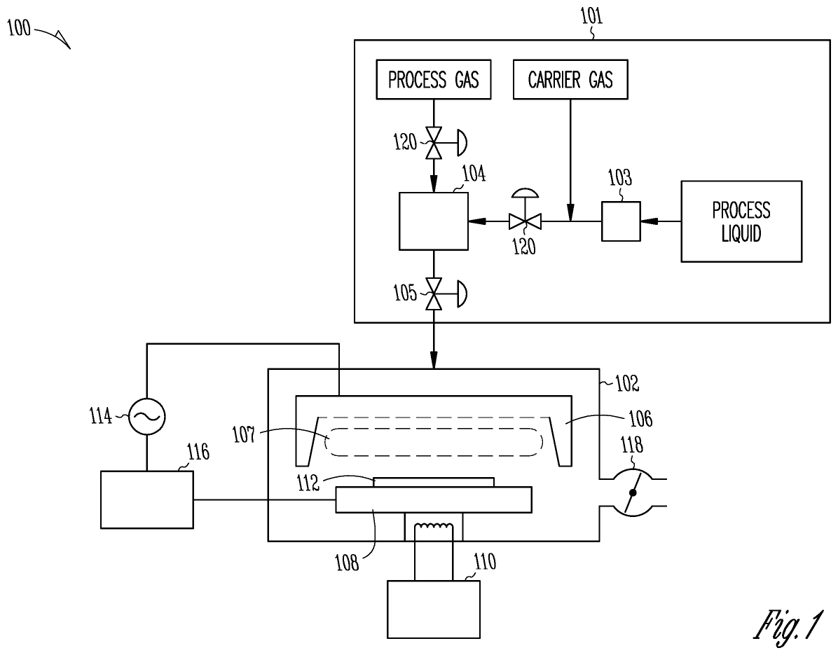

FIG. 1 depicts a schematic illustration of an embodiment of an atomic layer deposition (ALD) process station 100 having a process chamber body 102 for maintaining a low-pressure environment. A plurality of ALD process stations 100 may be included in a common low-pressure process tool environment. For simplicity, the ALD process station 100 is depicted as a standalone process station having a process chamber body 102 for maintaining a low-pressure environment. However, it will be appreciated that a plurality of ALD process stations 100 may be included in a common process tool environment. Further, it will be appreciated that, in some embodiments, one or more hardware parameters of ALD process station 100, including those discussed in detail below, may be adjusted programmatically by one or more computer controllers.

ALD process station 100 fluidly communicates with reactant delivery system 101 for delivering process gases to a distribution showerhead 106. Reactant delivery system 101 includes an optional mixing vessel 104 for blending and/or conditioning process gases for delivery to showerhead 106. One or more mixing vessel inlet valves 120 may control introduction of process gases to mixing vessel 104. Similarly, a showerhead inlet valve 105 may control introduction of process gasses to the showerhead 106. In another example, the reactant delivery system 101 may maintain the reactants separate from one another until delivery to inside the chamber body 102.

Some reactants, like silicon-containing precursors, such as, amino silane precursors (e.g., bis(t-butylamino)silane BTBAS, may be stored in liquid form prior to vaporization and subsequent delivery to the process station. Other precursors are possible. For example, the embodiment of FIG. 1 includes a vaporization point 103 for vaporizing liquid reactant to be supplied to mixing vessel 104. In some embodiments, vaporization point 103 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 103 may be heat traced. In some examples, mixing vessel 104 may also be heat traced. In one non-limiting example, piping downstream of vaporization point 103 has an increasing temperature profile extending from approximately 100° C. to approximately 150° C. at the mixing vessel 104.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a second pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 103. In one scenario, a liquid injector may be mounted directly to mixing vessel 104. In another scenario, a liquid injector may be mounted directly to showerhead 106.

In some embodiments, a liquid flow controller upstream of vaporization point 103 may be provided for controlling a mass flow of liquid for vaporization and delivery to ALD process station 100. For example, the liquid flow controller (LFC) may include a thermal mass flow meter (MFM) not shown. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 106 distributes process gases toward substrate 112. In the embodiment shown in FIG. 1, substrate 112 is located beneath showerhead 106, and is shown resting on a pedestal 108. It will be appreciated that showerhead 106 may have any suitable shape, and may have any suitable number and arrangement of ports for distributing processes gases to substrate 112.

In some embodiments, a microvolume 107 is located beneath showerhead 106. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 108 may be raised or seconded to expose substrate 112 to microvolume 107 and/or to vary a volume of microvolume 107. For example, in a substrate transfer phase, pedestal 108 may be seconded to allow substrate 112 to be loaded onto pedestal 108. During a deposition process phase, pedestal 108 may be raised to position substrate 112 within microvolume 107. In some embodiments, microvolume 107 may completely enclose substrate 112 as well as a portion of pedestal 108 to create a region of high flow impedance during a deposition process.

Optionally, pedestal 108 may be seconded and/or raised during portions the deposition process to modulate process pressure, reactant concentration, etc., within microvolume 107. In one scenario where process chamber body 102 remains at a base pressure during the deposition process, seconding pedestal 108 may allow microvolume 107 to be evacuated. Example ratios of microvolume to process chamber volume include, but are not limited to, volume ratios between 1:200 and 1:10. It will be appreciated that, in some embodiments, pedestal height may be adjusted programmatically by a suitable computer controller.

In another scenario, adjusting a height of pedestal 108 may allow a plasma density to be varied during plasma activation and/or treatment cycles included in the deposition process. At the conclusion of the deposition process phase, pedestal 108 may be seconded during another substrate transfer phase to allow removal of substrate 112 from pedestal 108.

While the example microvolume variations described herein refer to a height-adjustable pedestal, it will be appreciated that, in some embodiments, a position of showerhead 106 may be adjusted relative to pedestal 108 to vary a volume of microvolume 107. Further, it will be appreciated that a vertical position of pedestal 108 and/or showerhead 106 may be varied by any suitable mechanism within the scope of the present disclosure. In some embodiments, pedestal 108 may include a rotational axis for rotating an orientation of substrate 112. It will be appreciated that, in some embodiments, one or more of these example adjustments may be performed programmatically by one or more suitable computer controllers.

Returning to the embodiment shown in FIG. 1, showerhead 106 and pedestal 108 electrically communicate with RF power supply 114 and matching network 116 for powering a plasma. In some embodiments, the plasma energy may be controlled by controlling one or more of a process station pressure, a gas concentration, an RF source power, an RF source frequency, and a plasma power pulse timing. For example, RF power supply 114 and matching network 116 may be operated at any suitable power to form a plasma having a desired composition of radical species. Examples of suitable powers are included above. Likewise, RF power supply 114 may provide RF power of any suitable frequency. In some embodiments, RF power supply 114 may be configured to control high- and low-frequency RF power sources independently of one another. Example low-frequency RF frequencies may include, but are not limited to, frequencies between 50 kHz and 200 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe or an impurity reduction process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 108 may be temperature controlled via heater 110. Further, in some embodiments, pressure control for ALD process station 100 may be provided by butterfly valve 118. As shown in the embodiment of FIG. 1, butterfly valve 118 throttles a vacuum provided by a downstream vacuum pump (not shown). However, in some embodiments, pressure control of ALD process station 100 may also be adjusted by varying a flow rate of one or more gases introduced to ALD process station 100.

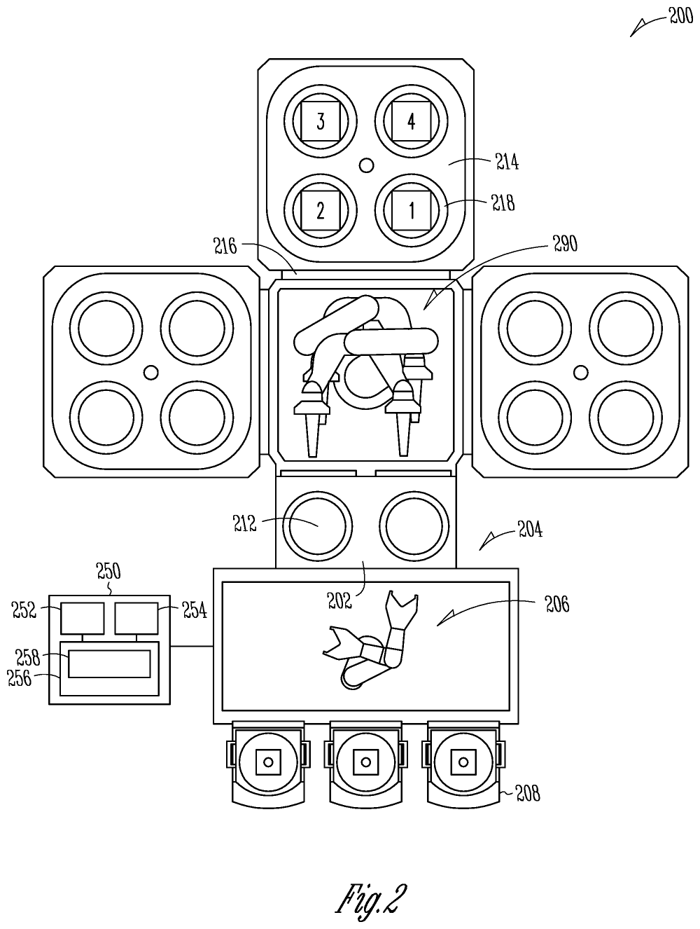

One or more process stations may be included in a multi-station processing tool. FIG. 2 shows a schematic view of an embodiment of a multi-station processing tool 200 with an inbound load lock 202 and an outbound load lock 204, either or both of which may comprise a remote plasma source. A robot 206, at atmospheric pressure, is configured to move substrates or wafers from a cassette loaded through a pod 208 into inbound load lock 202 via an atmospheric port 210. A substrate is placed by the robot 206 on a pedestal 212 in the inbound load lock 202, the atmospheric port 210 is closed, and the load lock is pumped down. Where the inbound load lock 202 comprises a remote plasma source, the substrate may be exposed to a remote plasma treatment in the load lock prior to being introduced into a processing chamber 214. Further, the substrate also may be heated in the inbound load lock 202 as well, for example, to remove moisture and adsorbed gases. Next, a chamber transport port 216 to processing chamber 214 is opened, and another robot (not shown) places the substrate into the reactor on a pedestal of a first station shown in the reactor for processing. While the embodiment depicted in FIG. 2 includes load locks, it will be appreciated that, in some embodiments, direct entry of a substrate into a process station may be provided. In various embodiments, the soak gas is introduced to the station when the substrate is placed by the robot 206 on the pedestal 212.

The depicted processing chamber 214 comprises four process stations, numbered from 1 to 4 in the embodiment shown in FIG. 2. Each station has a heated pedestal (shown at 218 for station 1), and gas line inlets. It will be appreciated that in some embodiments, each process station may have different or multiple purposes. For example, in some embodiments, a process station may be switchable between an ALD and plasma-enhanced ALD (PEALD) process mode. Additionally, or alternatively, in some embodiments, processing chamber 214 may include one or more matched pairs of ALD and plasma-enhanced ALD process stations. While the depicted processing chamber 214 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 2 depicts an embodiment of a wafer handling system 290 for transferring substrates within processing chamber 214. In some embodiments, wafer handling system 290 may transfer substrates between various process stations and/or between a process station and a load lock. It will be appreciated that any suitable wafer handling system may be employed. Non-limiting examples include wafer carousels and wafer handling robots. FIG. 2 also depicts an embodiment of a system controller 250 employed to control process conditions and hardware states of processing tool 200. System controller 250 may include one or more memory devices 256, one or more mass storage devices 254, and one or more processors 252. Processor 252 may include a CPU or computer, analog and/or digital input/output connections, stepper motor controller boards, etc. In some embodiments, system controller 250 includes machine-readable instructions for performing operations such as those described herein.

In some embodiments, system controller 250 controls the activities of processing tool 200. System controller 250 executes system control software 258 stored in mass storage device 254, loaded into memory device 256, and executed on processor 252. Alternatively, the control logic may be hard coded in the system controller 250. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 258 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by processing tool 200. System control software 258 may be configured in any suitable way. For example, various process tool component subroutines or control objects may be written to control operation of the process tool components used to carry out various process tool processes. System control software 258 may be coded in any suitable computer readable programming language.

Broadly speaking, the system controller 250 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 250 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 250, in some implementations, may be a part of or coupled to a computer that is integrated with, coupled to the system, otherwise networked to the system, or a combination thereof. For example, the system controller 250 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 250 receives instructions in the form of data, which specify parameters for each of the processing steps to be performed during one or more operations. It should be understood that the parameters may be specific to the type of process to be performed and the type of tool that the system controller 250 is configured to interface with or control. Thus, as described above, the system controller 250 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

The ALD process station 100 may also be used for CVD processes. It should be noted that references in this specification to ALD include within their scope PEALD and Thermal ALD, and references to CVD include within their scope PECVD and Thermal CVD. Some examples use a combination of ALD followed by CVD. In other words, an ALD process can be used to deposit a film of a certain thickness and then switched to a CVD process, and vice versa.

In some examples, during processing of a substrate in a processing chamber, an annealing operation is performed on the substrate or on a film deposited upon it. The annealing operation is performed in-situ, i.e., within the processing chamber and not at an external tool or furnace. To that end, an annealing gas may be introduced into the processing chamber by a gas delivery system. In some examples, the annealing gas includes H₂ and/or O₂, or a mixture thereof. In some examples, an annealing gas includes H₂ supplied at a flow rate in the range 500-10000 standard cubic centimetres per minute (sccm), and/or O₂ supplied at a flow rate in the range 500-10000 sccm. An annealing gas may, or may not, include an inert gas, such as Argon (Ar). In some examples, Ar is present in an annealing gas the range 2000-20000 sccm. Example annealing process parameters may include an annealing pressure in the range 5-30T, and an annealing temperature in the range 500-1000 C.

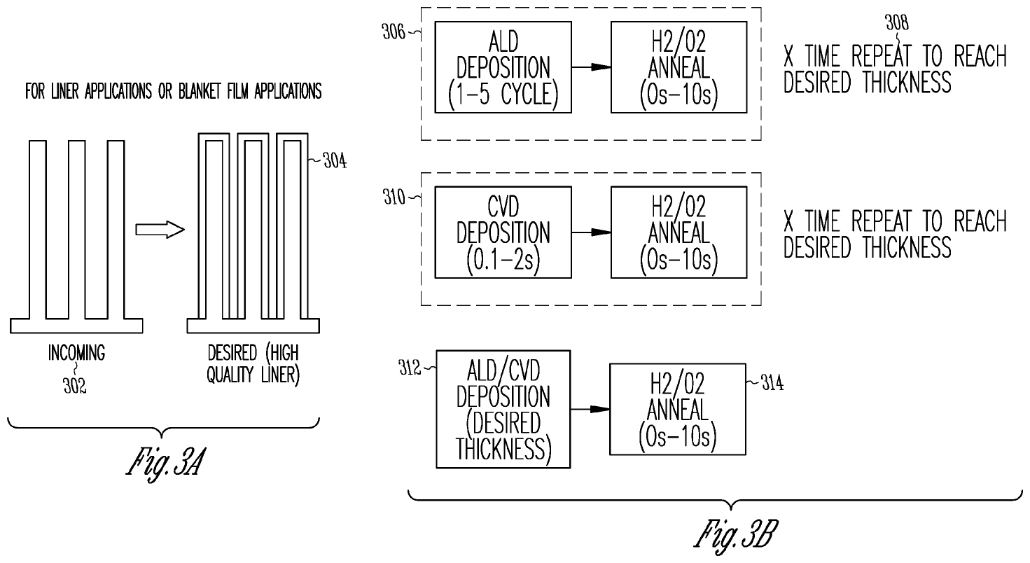

With reference now to FIGS. 3A-3B, some example annealing operations are shown in relation to liner or blanket film applications. One or more annealing gasses are introduced at 302 into a substrate processing chamber after an ALD cycle, post SiO₂ conversion. In some examples, a precursor gas may, or may not, be included in an annealing operation. A desired film or film quality 304 on the substrate can be configured by making one or more adjustments to the annealing operation. For example (A), in an initial film deposition operation, one or more cycles 306 of ALD SiO₂ may be performed, followed by a short H₂/O₂ annealing operation using an annealing gas (for example as described above). These deposition and annealing operations can be repeated at 308 a number of times to reach a desired film thickness. In example (B), the abovementioned annealing examples described with reference to or in association with ALD are also applicable to CVD as shown at 310. In example (C), all of a desired film thickness (i.e. a complete film thickness) is deposited first at 312, followed by a longer annealing time at 314 (for example, an annealing time in the range 2-30 minutes) to anneal the film completely. In the above, the annealing operations are performed in-situ.

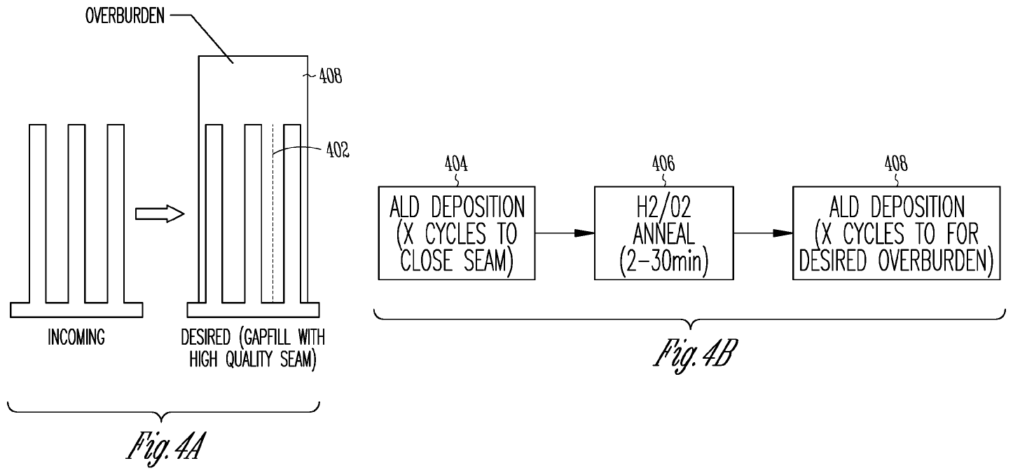

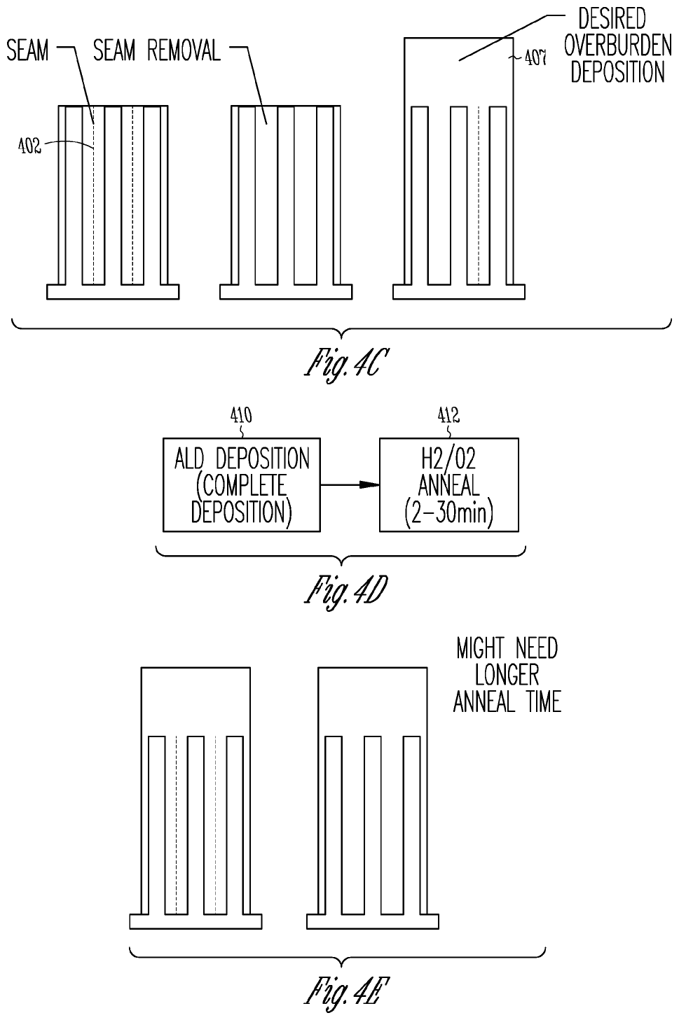

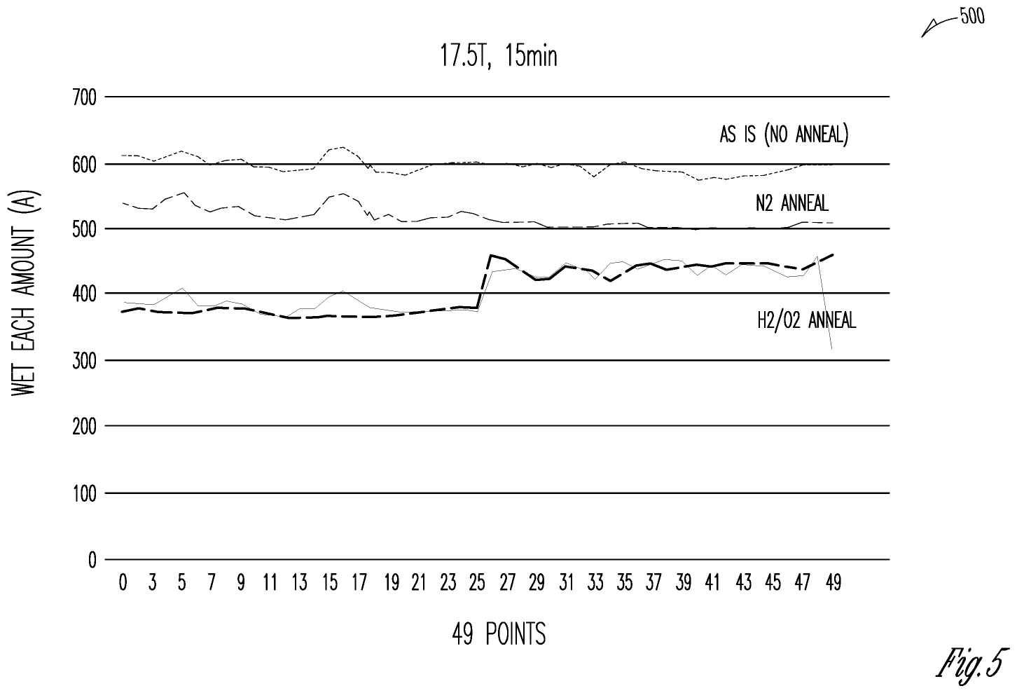

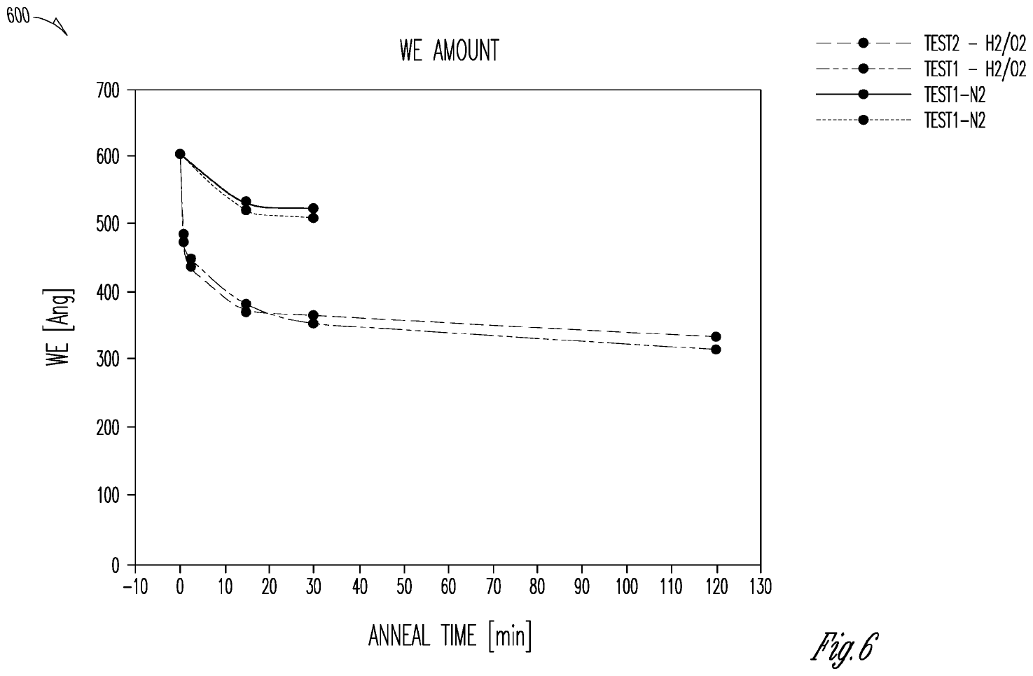

With reference to FIGS. 4A-4E, some examples operations are provided for gap fill applications in seam healing. Here, sufficient ALD oxide is deposited for an affected seam 402 to close. In example (A), a deposition 404 is followed by an H₂/O₂ annealing operation 406 using an annealing gas as described above, for example, for an annealing time in the range 2-30 minutes. A seam overburden 407 is then deposited at 408. In a further seam healing example (B), all of a desired film thickness (i.e. a complete film thickness) is initially deposited at 410 using ALD, followed at 412 by an H₂/O₂ anneal using one or more of the annealing gases or parameters described above, for example.

In some CVD examples, both a deposition precursor and a reactant may be simultaneously delivered to a process chamber to generate a processing environment in the chamber that includes both the deposition precursor and the reactant. In some embodiments, the deposition precursor and the reactant flow are turned on at different times, but there is at least some duration for which both flow of the deposition precursor and flow of the reactant are on at the same time, thereby creating a processing environment in the process chamber that includes both the deposition precursor and the reactant. This thermal CVD process may be performed for any suitable duration. The duration of this operation as described herein is based on a duration in which the substrate is exposed to a processing environment that includes both a deposition precursor and a reactant. On this basis, a deposition rate may be between about 3 Å/s and about 16 Å/s or at least about 12 Å/s. The pressure of the process chamber may be between about 9 Torr and about 30 Torr. The gas flow rates may depend on the gases being used. In some embodiments, hydrogen is co-flowed with an oxidant at a flow rate of between 0 sccm and about 5000 sccm. Where hydrogen is not co-flowed, hydrogen's flow rate is 0 sccm in some examples. One advantage of thermal CVD over ALD is a higher CVD deposition rate of ˜12 Å/s versus a second ALD rate of ˜1A/cycle while achieving the same process significantly faster.

In some examples, the annealing operation is performed for a duration of 1-30 minutes. In some examples, an annealing operation is performed at a chamber pressure in the range 5-30T. In some examples, an annealing operation is performed at a temperature in the range 500-700° C. In some examples, anneal conditions include H₂ introduced at 3-5 Standard Liters Per Minute (SLM), O₂ introduced at 3-5 SLM, chamber pressure in the range 17-30T, and temperature in the range 500-7000 Centigrade.

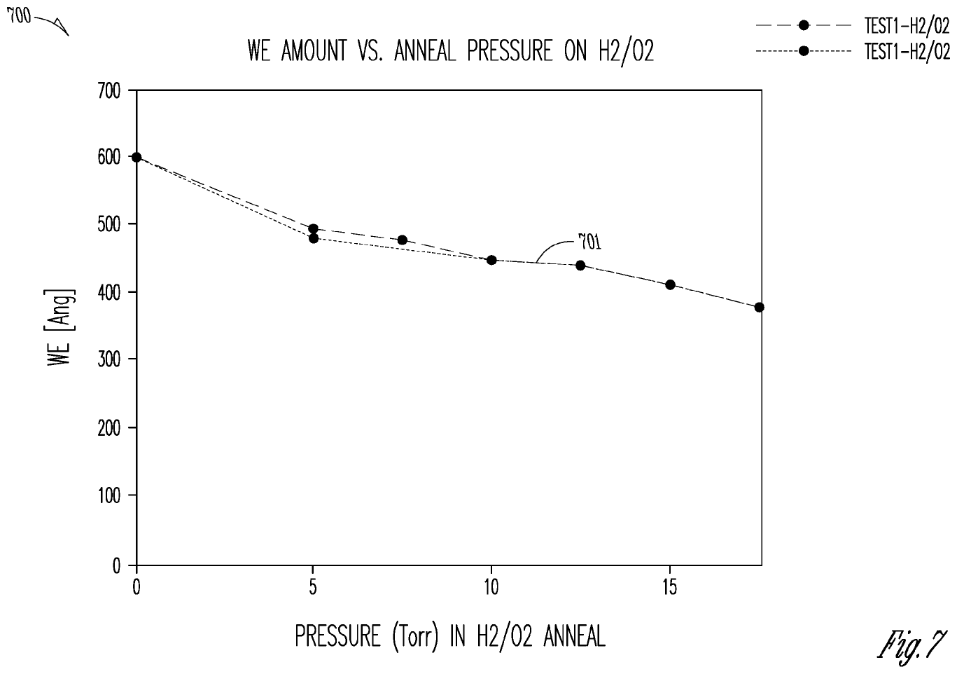

FIG. 5 shows a graph 500 depicting comparative experimental wet etch data for an example film annealed in-situ in a processing chamber in accordance with the annealing conditions discussed above. In some examples, the in-situ H₂/O₂ annealing operations performed on the examples films or substrates described herein are characterized by being performed within the processing chamber itself (i.e. in-chamber) without the need for removal of the film or substrate from the processing chamber for performance of the H₂/O₂ annealing operations. Wet etch data, such as WERs, may be considered a proxy for, or an aspect of, film quality. A low WER corresponds to a higher quality film. A higher quality film generally leads to better feature formation. At a chamber pressure of 17.5 Torr (T) for an annealing period of 15 minutes, example wet etch results were obtained for forty nine film locations in an area of a seam for a no anneal set, a neutral (external) nitrogen anneal set, and an example H₂/O₂ set annealed in-situ in accordance with this disclosure. It will be seen that the in-situ H₂/O₂ annealing was more effective at reducing WERs compared to the inert annealing of the film with nitrogen.

FIG. 6 shows a graph 600 depicting comparative experimental wet etch data for two example films (Test 1 H₂/O₂ and Test 2 H₂/O₂) annealed in-situ in a processing chamber in accordance with the following example annealing conditions. The conditions included a chamber pressure of 17.5T held over a variable annealing time as indicated on the graph 600, H₂ introduced at 5 SLM, O₂ introduced at 5 SLM, and Argon (Ar) introduced at 20 SLM. The wet etch data derived for Test 1 H₂/O₂ and Test 2 H₂/O₂ was plotted against comparative data for Test 1 N₂ and Test 2 N₂ films annealed conventionally (i.e. externally of the processing chamber) with nitrogen for the indicated annealing times. The Test 1 H₂/O₂ and Test 2 H₂/O₂ examples exhibited significantly second wet etch rates, as shown by the graph 800.

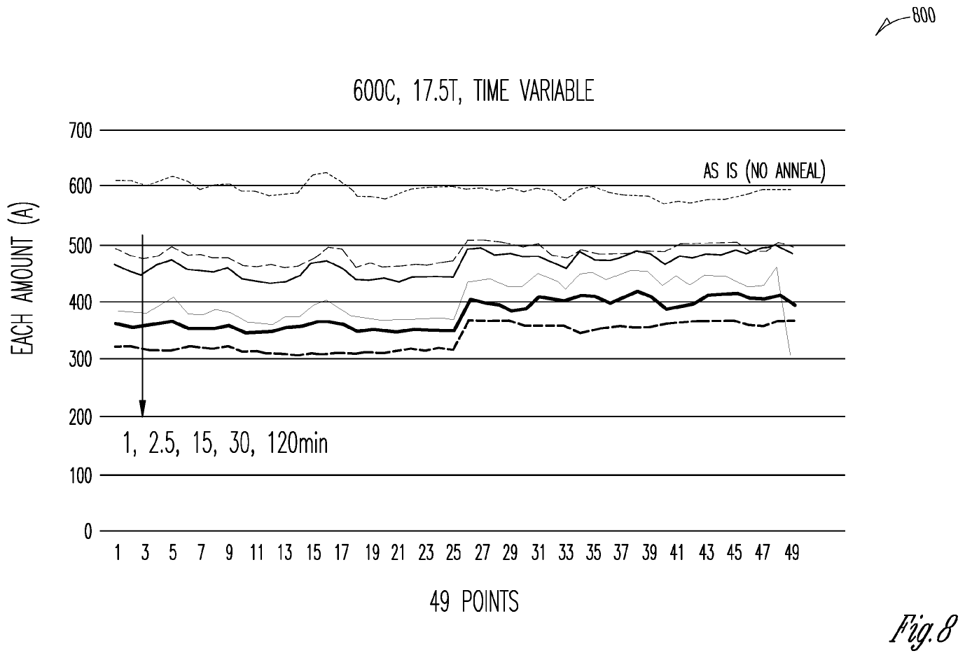

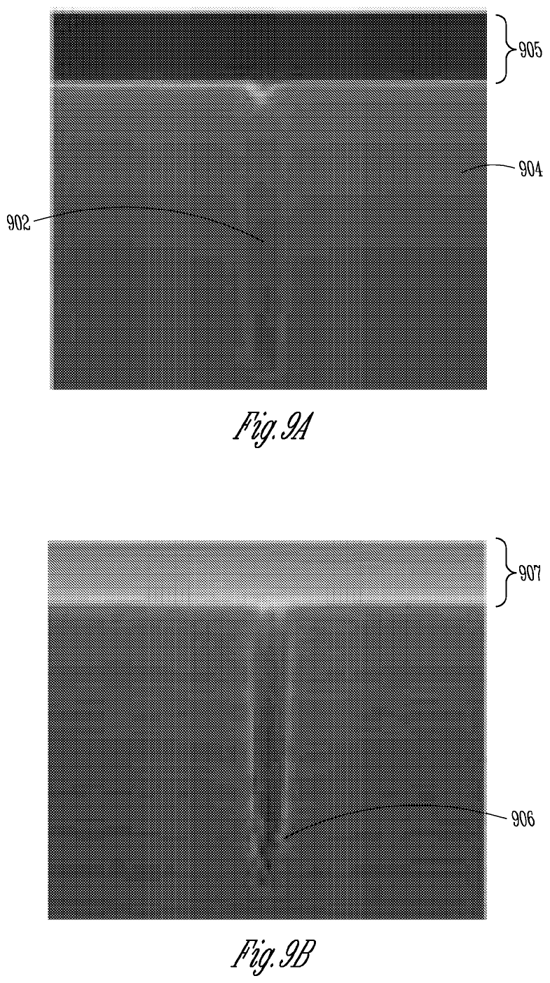

In some examples, annealing conditions were configured to improve film quality faster or reduce wet etch rates in a more impactful way. To this end, examples were tested under variable pressure. The downward sloping graph line 701 in graph 700 in FIG. 7 indicates that increasing chamber pressure during in-situ annealing was helpful in reducing wet etch rates. Further examples were also tested under variable time. For example, the graph 800 in FIG. 8 indicates that wet etching may be reduced by increasing annealing times in the range 1 to 120 minutes, with times within that range tested at 2.5, 15, and 30 minutes. Annealing conditions for the tested examples of graph 800 included chamber temperature at 600° Centigrade, chamber pressure at 17.5T held over variable times as shown in the graph 800, measured at forty-nine film locations in an area of a seam.

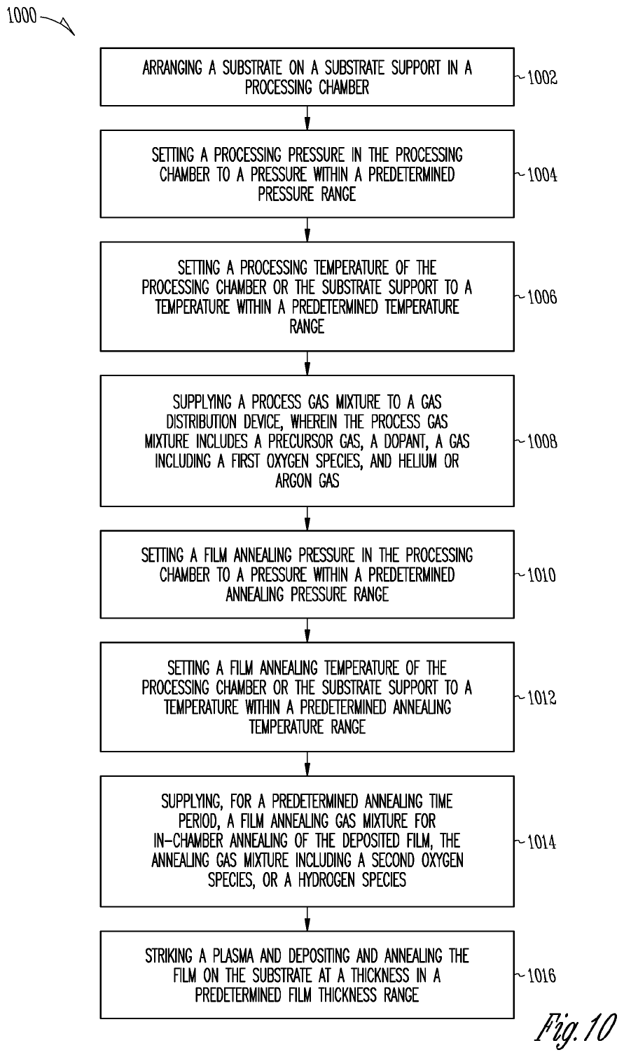

In some examples, the use of hydrogen and/or oxygen in in-situ film annealing operations provides an inexpensive delivery vehicle as compared to the use of other gases. Some H₂/O₂ examples can be used to heal seams (for example see FIGS. 9A-9B described below), or in gap fill applications. Some H₂/O₂ examples may include multiple or repeated annealing operations. In some examples, one or more annealing operations interchange with one or more deposition operations. In such examples, one or more interchanging annealing and deposition operations may respectively be the same (i.e. a repeat operation) in each cycle or vary from cycle to cycle. Interchanging deposition and annealing operations may be useful if varying dimensions are present or required on a given wafer or substrate. In-situ annealing methods and configurations of this disclosure can provide effective solutions in this regard.

FIGS. 9A-9B illustrate an example beneficial impact of in-situ annealing on an example seam in a film, according to some examples. In FIG. 9A, some defects 902 are formed or remain present in a seam 904 of a film 906 when annealed using conventional methods. Using present methods, as shown in FIG. 9B, the seam 904 is notably improved and the defects 902 have been removed.

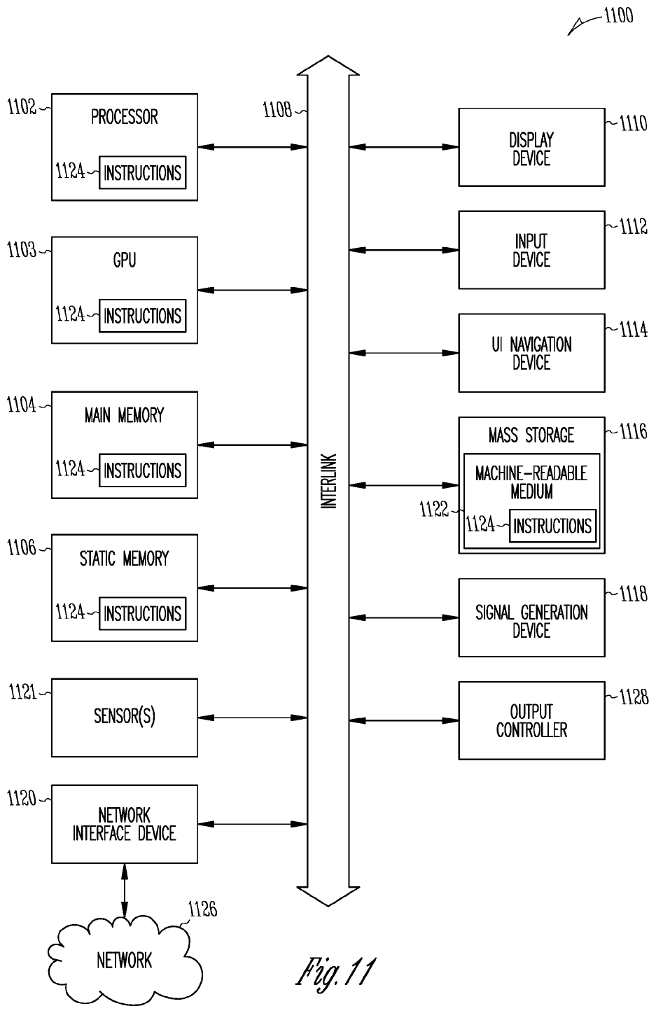

Some of the embodiments disclosed herein include methods. With reference to FIG. 10, operations in a method 1000 of depositing film on a substrate includes, at operation 1002, arranging a substrate on a substrate support in a processing chamber; at operation 1004, setting a processing pressure in the processing chamber to a pressure within a predetermined pressure range; at operation 1006, setting a processing temperature of the processing chamber or the substrate support to a temperature within a predetermined temperature range; at operation 1008, supplying a process gas mixture to a gas distribution device, wherein the process gas mixture includes a precursor gas, an optional dopant or dopants, a gas including a first oxygen species, and an inert gas such as helium or argon gas; at operation 1010, setting a film annealing pressure in the processing chamber to a pressure within a predetermined annealing pressure range; at operation 1012, setting a film annealing temperature of the processing chamber or the substrate support to a temperature within a predetermined annealing temperature range; at operation 1014, supplying, for a predetermined annealing time period, a film annealing gas mixture for in-chamber annealing of the deposited film, the annealing gas mixture including a second oxygen species, or a hydrogen species; and, at operation, 1016, striking a plasma and depositing and annealing the film on the substrate at a thickness in a predetermined film thickness range.

In some examples, the hydrogen species of the annealing gas mixture includes H₂ introduced at a flow rate in the range 500-10000 standard cubic centimeters per minute (sccm).

In some examples, the second oxygen species of the annealing gas mixture includes O₂ introduced at a flow rate in the range 500-10000 sccm.

In some examples, the method 1000 further comprises supplying the precursor gas, the optional dopant(s), the gas including the oxygen species, and the inert gas to a mixing manifold to create the process gas mixture; supplying the second oxygen species, or the hydrogen species, to the mixing manifold to create the annealing gas mixture; and delivering the process gas mixture and annealing gas mixture to the gas distribution device arranged above the substrate support.

In some examples, the method 1000 further comprising supplying a secondary purge gas to the processing chamber.

In some examples, the secondary purge gas includes argon.

In some examples, the predetermined annealing pressure range is 5-30T.

In some examples, the predetermined annealing temperature range is 500-700° C.

In some examples, the predetermined annealing time period is in the range 1-30 minutes.

In some examples, striking the plasma, at the processing chamber or at a multi-station tool comprises supplying HF power for one of an first electrode and a second electrode in a range from 1000 to 6500 W and LF power for one of the first electrode and the second electrode in a range from 500 to 6500 W.

In some examples, striking the plasma comprises supplying HF power to one of an first electrode and a second electrode in a range from 2000 to 3000 W and LF power to the one of the first electrode and the second electrode in a range from 1000 to 3000 W.

In some examples, the gas including the first oxygen species includes molecular oxygen.

In some examples, the gas including the first oxygen species is supplied at the processing chamber or at a multi-station tool at a flow rate in a range from 15 slm to 30 slm (standard liters per minute).

In some examples, the gas including the first oxygen species is supplied at the processing chamber or at a multi-station tool at a flow rate in a range from 20 slm to 25 slm.

In some examples, the precursor gas is supplied at the processing chamber or at a multi-station tool at a flow rate in a range from 40 sccm to 70 sccm (standard cubic centimeters per minute).

FIG. 11 is a block diagram illustrating an example of a machine, such as the system controller 1100, by which one or more example process embodiments described herein may be controlled. In alternative embodiments, the system controller 1100 may operate as a standalone device or may be connected (e.g., networked) to other machines. In some examples, the system controller 1100 may be comprised by or include the system controller 250 of FIG. 2. In a networked deployment, the system controller 1100 may operate in the capacity of a server machine, a client machine, or both in server-client network environments. In an example, the system controller 1100 may act as a peer machine in a peer-to-peer (P2P) (or other distributed) network environment. Further, while only a single machine (i.e., the system controller 1100) is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, a number of components or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, by moveable placement of invariant massed particles, etc.) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The system controller (e.g., computer system) 1100 may include a hardware processor 1102 (e.g., a central processing unit (CPU), a hardware processor core, or any combination thereof), a graphics processing unit (GPU) 1103, a main memory 1104, and a static memory 1106, some or all of which may communicate with each other via an interlink (e.g., bus) 1108. The system controller 1100 may further include a display device 1110, an alphanumeric input device 1112 (e.g., a keyboard), and a user interface (UI) navigation device 1114 (e.g., a mouse). In an example, the display device 1110, alphanumeric input device 1112, and UI navigation device 1114 may be a touch screen display. The system controller 1100 may additionally include a mass storage device (e.g., drive unit) 1116, a signal generation device 1118 (e.g., a speaker), a network interface device 1120, and one or more sensors 1121, such as a Global Positioning System (GPS) sensor, compass, accelerometer, or another sensor. The system controller 1100 may include an output controller 1128, such as a serial (e.g., universal serial bus (USB)), parallel, or other wired or wireless (e.g., infrared (IR), near field communication (NFC), etc.) connection to communicate with or control one or more peripheral devices (e.g., a printer, card reader, etc.).

The mass storage device 1116 may include a machine-readable medium 1122 on which is stored one or more sets of data structures or instructions 1124 (e.g., software) embodying or utilized by any one or more of the techniques or functions described herein. The instructions 1124 may also reside, completely or at least partially, within the main memory 1104, within the static memory 1106, within the hardware processor 1102, or within the GPU 1103 during execution thereof by the system controller 1100. In an example, one or any combination of the hardware processor 1102, the GPU 1103, the main memory 1104, the static memory 1106, or the mass storage device 1116 may constitute machine-readable medium 1122.

While the machine-readable medium 1122 is illustrated as a single medium, the term “machine-readable medium” may include a single medium or multiple media (e.g., a centralized or distributed database, and/or associated caches and servers) configured to store the one or more instructions 1124.

The term “machine-readable medium” may include any medium that can store, encode, or carry instructions 1124 for execution by the system controller 1100 and that cause the system controller 1100 to perform any one or more of the techniques of the present disclosure, or that can store, encode, or carry data structures used by or associated with such instructions 1124. Non-limiting machine-readable medium examples may include solid-state memories, and optical and magnetic media. In an example, a massed machine-readable medium comprises a machine-readable medium 1122 with a plurality of particles having invariant (e.g., rest) mass. Accordingly, massed machine-readable media are not transitory propagating signals. Specific examples of massed machine-readable media may include non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; and CD-ROM and DVD-ROM disks. The instructions 1124 may further be transmitted or received over a communications network 1126 using a transmission medium via the network interface device 1120.

Although an embodiment has been described with reference to specific example embodiments, it will be evident that various modifications and changes may be made to these embodiments without departing from the broader scope of the inventive subject matter. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover all adaptations or variations of various embodiments. Combinations of the above embodiments, and other embodiments not specifically described herein, will be apparent to those of skill in the art upon reviewing the above description.

What is claimed is:

1. A method for depositing a film on a substrate, the method comprising:
arranging a substrate on a substrate support in a processing chamber;
setting a processing pressure in the processing chamber to a pressure within a predetermined pressure range;
setting a processing temperature of the processing chamber or the substrate support to a temperature within a predetermined temperature range;
supplying a process gas mixture to a gas distribution device, wherein the process gas mixture comprises a precursor gas, a gas including a first oxygen species, and an inert gas;
striking a plasma and depositing a film on the substrate in a predetermined film thickness range;
performing, within the processing chamber, in-sins annealing operations on the deposited film, the in-situ annealing operations including, at least:
setting a film annealing pressure in the processing chamber to a pressure within a predetermined annealing pressure range;
setting a film annealing temperature of the processing chamber or the substrate support to a temperature within a predetermined annealing temperature range;
supplying, for a predetermined annealing time period, a film annealing gas mixture for in-situ annealing of the deposited film, the annealing gas mixture comprising at least one of a second oxygen species or a hydrogen species; and
annealing the film on the substrate.

2. The method of claim 1, wherein the hydrogen species of the annealing gas mixture comprises hydrogen (H₂) introduced, at the processing chamber, at a flow rate in the range 500-10000 standard cubic centimeters per minute (sccm).

3. The method of claim 1, wherein the second oxygen species of the annealing gas mixture comprises O₂ introduced, at the processing chamber, at a flow rate in a range 500-10000 sccm.

4. The method of claim 1, further comprising:
supplying the precursor gas, the gas comprising the first oxygen species, and the inert gas to a mixing manifold to create the process gas mixture;
supplying at least one of the second oxygen species, or the hydrogen species, to the mixing manifold to create the annealing gas mixture; and
delivering the process gas mixture and annealing gas mixture to the gas distribution device arranged above the substrate support.

5. The method of claim 1, further comprising supplying a purge gas to the processing chamber.

6. The method of claim 5, wherein the purge gas includes argon.

7. The method of claim 1, wherein the predetermined annealing pressure range is 5-30T.

8. The method of claim 1, wherein the predetermined annealing temperature range is 500-700° C.

9. The method of claim 1, wherein the predetermined annealing time period is in a range 1-30 minutes.

10. The method of claim 1, wherein striking the plasma, at the processing chamber or at a multi-station tool, comprises supplying high-frequency (HF) power for one of an first electrode and a second electrode in a range from 1000 to 6500 W and low-frequency (LF) power for one of the first electrode and the second electrode in a range from 500 to 6500 W.

11. The method of claim 10, wherein striking the plasma, at the processing chamber or at a multi-station tool, comprises supplying HF power for one of an first electrode and a second electrode in a range from 2000 to 3000 W and LF power for one of the first electrode and the second electrode in a range from 1000 to 3000 W.

12. The method of claim 1, wherein the gas including the first oxygen species includes molecular oxygen.

13. The method of claim 1, wherein the gas including the first oxygen species is supplied at a flow rate in a range from 15 slm to 30 slm (standard liters per minute).

14. The method of claim 1, wherein the gas including the first oxygen species is supplied at a flow rate in a range from 20 slm to 25 slm.

15. The method of claim 1, wherein the precursor gas is supplied at a flow rate in a range from 40 sccm to 70 sccm (standard cubic centimeters per minute).

16. A system for depositing a film on a substrate, the system comprising:
a processing chamber;
a substrate support for supporting a substrate in the processing chamber;
a pressurizer configurable to set a processing and annealing pressure in the processing chamber to a predetermined pressure range, the annealing pressure set for an in-situ annealing of the film;
a heater configurable to set a processing and annealing temperature of the processing chamber or the substrate support to a predetermined temperature, the annealing temperature set for the in-situ annealing of the film;
a gas distribution device configurable to receive a supply of a process gas mixture and a film annealing gas mixture, wherein the process gas mixture comprises a precursor gas, a gas comprising a first oxygen species, and an inert gas, and wherein the film annealing gas mixture comprises at least one of a second oxygen species or a hydrogen species;
an electrode for striking a plasma to deposit the film in a predetermined thickness range; and
the processing chamber configured to anneal the deposited film in-situ based on the annealing pressure and temperature.
